(19) United States
(12) Patent Application Publication
(10) Pub. No.: US 2004/0166603 A1
(43) Pub. Date: Aug. 26, 2004

(54) Micromachined assembly with a multi-layer cap defining a cavity

(76) Inventor: L. Richard Carley, Sewickley, PA (US)

Correspondence Address: Mark G. Lappin, McDermott, Will & Emery, 28 State Street, Boston, MA, 02109, US

(21) Appl. No.: 10/374,150

(22) Filed: Feb. 25, 2003

(51) Int. Cl. H01L 21/00; H01L 29/06

(52) U.S. Cl. 438/52; 438/50; 257/618

(57) ABSTRACT

This invention comprises a process for fabricating a micro mechanical structure in a sealed cavity having a multi-layer high strength cap. The high strength material used for the cap protects the underlying microstructure from destructive environmental forces inherent in the packaging process and from environmental damage.

### FIELD OF THE INVENTION

This invention relates to the field of integrated circuits that incorporate microelectro-mechanical systems (MEMS) or other micro-mechanical devices, and, in particular, to the creation of sealed cavities for the encapsulation of said MEMS or micro-mechanical devices.

### BACKGROUND OF THE INVENTION

It is known in the prior art to create sealed cavities on an integrated circuit wafer for a variety of applications, for example, as a pressure sensor or a microphone. It is also known to encapsulate movable micro-mechanical components on a wafer within a sealed cavity. The encapsulation of micro-mechanical structures in a sealed cavity is desirable for several reasons. First, a seal that substantially prevents water vapor, dust and atmospheric gases from entering the space enclosing the micro-mechanical structure greatly improves the tolerance of the micro-mechanical structures to ambient conditions, such as high humidity. Second, the dicing and packaging of the wafers bearing micro-mechanical structures is greatly facilitated because standard water-based saw slurries can be used without concern that the slurry will contaminate the micro-mechanical structures. Third, when the sealed cavity is at a low or very low pressure, the Brownian noise due to the motion of gas molecules can be significantly reduced.

Processes for the creation of sealed cavities containing MEMS devices using thin-film depositions are well known in the prior art. For purposes of this application, the term “thin film deposition” refers to any deposition scheme in which the atoms are assembled from a gaseous or plasma phase onto the surface of the wafer bearing the micro-mechanical device(s). See, for example, U.S. Pat. No. 5,285,131 and U.S. Pat. No. 5,493,177 (both to Muller, et al.) in which methods to create an incandescent lamp and a vacuum tube respectively are disclosed. The use of thin-film deposition techniques is desirable, because of the accuracy with which the thin films can be patterned, the high quality of the adhesion of the thin films to the wafer surface, and the low cost involved in thin film deposition techniques compared to wafer-wafer bonding approaches.

A typical thin-film deposition process is as follows. A silicon substrate is covered with a protective layer that is selectively removed, thereby exposing the silicon wafer in the region to be encapsulated. Then, a layer of sacrificial material is deposited to support the structural layer as it is formed. The structural layer is deposited and patterned on the sacrificial layer, and is then covered by a second sacrificial layer. The second sacrificial layer supports a cap layer during its formation. To remove the sacrificial layers, thereby releasing the micro-mechanical device, holes are etched through the cap layer down to the sacrificial layers and an etching agent is introduced to remove the sacrificial layers. Once the MEMS device has been released, the holes in the cap layer are sealed by another thin-film deposition process. Complex structures may require additional layers of structural or sacrificial materials.

Typically, the cap layer is composed of a layer of silicon nitride. However, although silicon nitride is a very hard material, it is difficult to deposit in thick layers with good control of intrinsic stresses. Alternatively, caps have been made of metal, such as aluminum. In this case the cap thickness can be made greater; however, the material itself is ductile and can be deformed by pressure. Therefore, one problem with the capping technology that is available today is that the caps are relatively weak. Differences in pressure created when the sealed cavity encloses a vacuum can cause the cap to collapse inward. Additionally, stresses placed on the cap during packaging can cause the cap to collapse or to bow inward. For example, enclosing the wafer in plastic packaging exposes the cap to hot, high pressure plastic, often at temperatures up to about 300 degrees C., and pressures up to about 3000 psi, during the injection molding process. Such conditions can often damage the caps, resulting in the destruction of the fragile encapsulated microstructure. Caps constructed using the thin-film deposition technologies available today are not able to withstand such pressures.

To avoid damage during the packaging process, it is known in the prior art to cover micro-mechanical structures on a wafer with a second wafer made of silicon or glass, which has an etched cavity over the micro-mechanical structure, and which is in some way bonded to the original wafer bearing the micro-mechanical structures. Several methods are well known in the art for creating a bond between the wafer containing the micro-mechanical structures and the wafer that implements the cap. In particular, anodic bonding can be used. In addition, by depositing and patterning a eutectic metal alloy in the region where a seal is to be formed, the two wafers can be bonded in a process that is much like soldering. However, all of these two-wafer methods, in addition to adding significant expense to the processing thereof, reduce the available device area on the surface of the wafer due to space needed to support the capping wafer seal to the micro-mechanical wafer, thereby resulting in fewer devices per wafer and increasing the cost per device.

Therefore, it would be desirable to introduce a way to strengthen a thin-film cap to encapsulate a micro-mechanical device such that it is not susceptible to damage caused by the difference in pressure between the scaled cavity and the ambient or by the harsh environment that it may be exposed to during the plastic injection molding process, and which also conserves wafer real estate.

### SUMMARY OF THE INVENTION

This invention is an improvement on the prior art method of sealing encapsulated MEMS devices. The improvement involves forming a thin-film cap from a layer of a material characterized by a high strength or stiffness relative to known capping materials, such as, for example, aluminum oxide or alumina (Al₂O₃), which is many times stronger than the prior art aluminum caps. While silicon nitride may be as strong, on a per unit basis, as alumina, there is no known way to deposit thick, low stress silicon nitride layers. The overall strength of a cap is a function of both the hardness of the material of which the cap is constructed, and the thickness of the cap. It is known to deposit low stress layers of alumina layers, as would be found in heads of magnetic disk drives, however, there are no known uses of alumina in the manufacture or encapsulation of MEMS devices.

It is known in the prior art that silicon nitride may be used to provide a seal over a cavity. However, it is not known to deposit a strong, stress-free layer of silicon nitride which is thick and rigid enough to sustain the pressures, temperatures and stresses of plastic packaging. Prior art attempts to create thick layers of silicon nitride have resulted in caps having a very high intrinsic stress gradient, which tends to cause the cap to pull away from the wafer, destroying the seal of the cavity.

The present invention features a micromachined assembly that includes a substrate, a microstructure optionally disposed on the substrate, and a cap structure that defines a closed capsule about an interior region containing the microstructure. In particular, in a micromachined assembly constructed in accordance with one embodiment of the invention, the substrate has a support surface upon which a microstructure may be disposed. A cap layer extends from points on the support surface disposed about the microstructure. The cap layer includes a portion overlying the microstructure. A cap overlayer extends from the support surface and is disposed over, and contiguous with, the cap layer. The cap layer, the cap overlayer and the support surface define a closed capsule about an interior region which may contain a microstructure. In a preferred embodiment, the cap structure is characterized by a high stiffness relative to know prior art materials. Preferably, the stiffness of the cap structure is sufficient to withstand a uniform pressure equivalent to up to about 60 atmospheres, with no portion of the cap structure deflecting by more than 1 micrometer from its initial position. Existing thin-film capping methods in the prior art cannot achieve such stiffness because the thin film layers as taught in the prior art cannot be deposited thick enough in the size ranges of interest for capping typical microstructures.

Examples of typical microstructures which may require encapsulation include, but are not limited to, a micro-electro-mechanical system (MEMS), a surface acoustic wave (SAW) device, a film bulk acoustic resonator, an integrated circuit (IC), or a capacitive sense plate adapted to measure ambient pressure due to a variation in the spacing between the substrate and the inner surface of the cap layer.

In one embodiment of the invention, the cap layer includes a top portion distalmost from the support surface. The top portion ideally extends in a direction substantially parallel to the support surface. The cap layer also includes a lateral portion extending between the top portion and the support surface. The cap layer may include one or more ports or openings extending therethrough for purposes of introducing an etching agent into the cavity to remove any sacrificial material used in the construction of the cap layer and/or any microstructures which may be contained in the cavity. In one embodiment, the ports may be disposed in the lateral portion of the cap layer in a direction substantially transverse to a normal to the support surface. Alternatively, the ports may be disposed in the top portion of the cap layer. In yet another embodiment, the substrate may include one or more ports extending therethrough in a direction substantially transverse to a normal to the support surface. The interior region within the closed capsule may be substantially filled with a noble gas. The application of a multilayer cap overlayer serves to seal the ports.

In a preferred embodiment, the cap overlayer is a multilayer structure, and has an innermost layer contiguous with the cap layer. The cap overlayer may be formed of a relatively high energy sputtered material. At least the lowermost layer within the multilayer structure is a relatively high energy RF sputtered material. For example, the lowermost layer may be a thin film deposited using RF plasma sputtering. At least two adjacent layers of the cap overlayer may be layers of a high strength material (such as alumina), and at least one of the adjacent layers is preferably an RF-sputtered layer. The cap overlayer may be a graded density structure, but preferably does not have a relatively high density region contiguous with the cap layer.

This invention in one form is directed to devices made by a process which includes the deposition of one or more layers of a material or materials which have low intrinsic stress or which are stress-free, and which are rigid enough to withstand the rigors of plastic packaging. Alumina is a preferred material. Additionally, other ionic or covalently bonded materials may also be used (in place of alumina) that have high strength and stiffness relative to prior art materials, and that can withstand the rigors of plastic packaging. Thus, the cap materials which can be chosen for such applications include ionic bonded, covalently bonded, or mixed ionic and covalent bonded materials.

In one exemplary embodiment of the invention, a cap layer made of a high-strength material, namely alumina, may be deposited by a traditional sputtering process, or by other deposition processes, as a multi-layer structure. During the deposition of the alumina cap, it is important to avoid or at least minimize the format of voids in the cap structure at places where sharp edges exist in the underlying inner cap layer or structure layers or sacrificial layers. Voids within a cap overlayer may concentrate stress and possibly lead to the eventual failure of the seal. In addition, in cases where the device is to be dispersed in a molded plastic package (formed by injecting hot plastic from the side of the micromachined cap device), it is desirable to have the edges of the cap be smooth and conformal to decrease the forces on the cap during plastic injection molding.

To minimize the formation of voids and to make the surface of the cap more conformal, the cap is preferably deposited in several layers under varying deposition conditions. In certain exemplary embodiments of the invention, the various layers of the cap may be applied using sputtering deposition techniques with varying bias voltages between the source and deposition substrate and under varying deposition ambient pressures to control the microstructure properties of one or more of the layers that make up the overall cap seal layer. Such a multi-layer deposition process results in a reduction of stress within the deposited material forming the cap, resulting in a very low intrinsic stress gradient in the cap, providing resistance to buckling under high ambient pressure.

In addition, the deposition parameters for layers immediately in contact with the underlying wafer must be selected to provide good and uniform adhesion of the cap layer to the underlying wafer near the perimeter of the cavity, where the cap meets the wafer surface. This good and uniform adhesion of the cap effects a good barrier to gases and prevents the cap from separating from the wafer due to intrinsic stress or when subjected to environmental stresses. In the example of a sputtering deposition system, the wafer surface is preferably sputter cleaned before the deposition begins to further improve the adhesion of the cap layer to the underlying surface.

### DESCRIPTION OF THE DRAWINGS

FIGS. 1A and 1B show a top view and a side cross-sectional view respectively of the silicon CMOS wafer used as the base of the MEMS micro-encapsulated structure.

FIGS. 2A and 2B show a top view and a cross-sectional view respectively of the wafer with a sacrificial layer deposited thereon.

FIGS. 3A and 3B show a top view and a cross-sectional view respectively of the wafer having a structural layer added thereon.

FIGS. 4A and 4B show a top view and a cross-sectional view respectively of the wafer having a second sacrificial layer deposited thereon.

FIGS. 5A, 5B and 5C show a top view and cross-sectional views respectively of the wafer having a mask applied thereto to etch holes for the supporting pillars of the cap layer.

FIGS. 6A, 6B and 6C show a top view and cross-sectional views respectively of the wafer having a cap deposited thereon, with supporting pillars.

FIGS. 7A, 7B and 7C show a top view and two cross-sectional views respectively of the wafer after the sacrificial layers have been etched away.

FIGS. 8A and 8B, 8C and 8D show a top view and several cross-sectional views respectively of the wafer having three alumina layers applied thereon.

FIGS. 9A and 9B show an embodiment of the invention using pillars to create lateral etchant access holes.

### DETAILED DESCRIPTION

Disclosed herein are methods of creating high-strength caps for the creation of cavities enclosing regions of interest on wafer surfaces and techniques to prevent the formation of voids in the caps, where the caps are comprised of a high-strength material, such as, for example, alumina, and are preferably deposited using a process designed to increase the rigidity and strength of the cap as well as its adhesion to the wafer surface.

In the following description of exemplary embodiments, an exemplary MEMS microstructure that can be utilized as a Z-axis accelerometer will be used to facilitate the description. The exemplary MEMS device consists of a paddle shaped MEMS microstructure anchored at one point by a thin supporting shaped MEMS microstructure anchored at one point by a thin supporting member such that it can move in the Z direction within the sealed cavity. This structure is meant to be an exemplar only to illustrate the methods disclosed herein, and is not meant to limit the scope of the present disclosure. One skilled in the art will appreciate that the exemplary methods and the exemplary caps disclosed herein may be used in connection with other MEMS microstructures or other devices, or with cavities which are void of internal microstructures, and the invention is therefore not meant to be limited thereby.

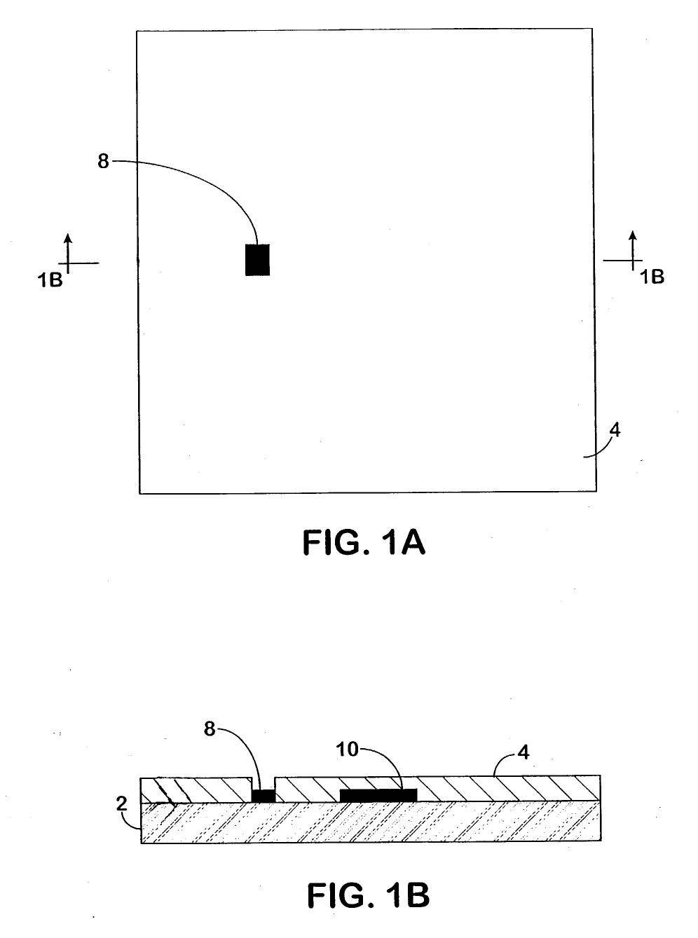

The figures illustrate an exemplary sequence of steps for fabricating an encapsulated microstructure. Initially, a substrate such as, for example, a silicon CMOS wafer 2 coated with a layer of silicon nitride 4 and having metal pads 8 and 10 interfacing to the original CMOS integrated circuit is obtained, as shown in FIGS. 1A and 1B. The substrate has a support surface which defines a portion of the wall of the cavity. In one embodiment, the substrate may be a CMOS structure, with the support surface being a passivation layer, and may include CMOS circuitry defined within the substrate. In this exemplar, a void is disposed in silicon nitride layer 4 to allow access to metal pad 8. In the illustrated exemplary embodiment, the metal pads are aluminum, but may alternatively be copper or any other conductive material. Note, that it is not necessary that a silicon wafer with CMOS or any other form of electronics be used for this process, or that the wafer itself be silicon. One skilled in the art will appreciate that the invention is applicable to wafers composed of any material, such as, for example, gallium arsenide.

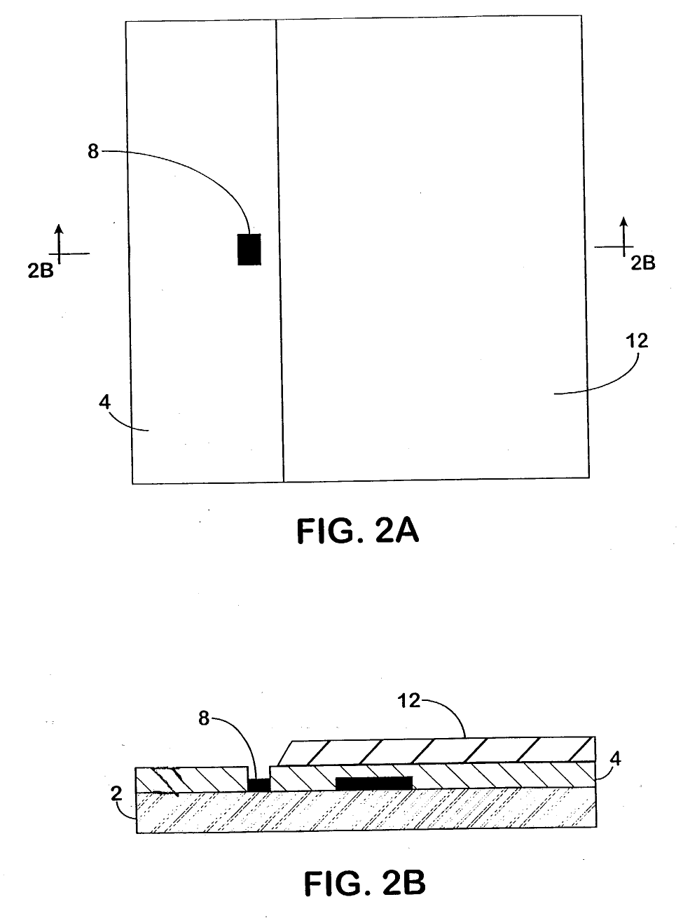

To begin the fabrication process, as shown in FIGS. 2A, 2B and 2C, a layer of sacrificial material 12 is deposited on top of the passivation layer of the standard CMOS wafer 2, which in this case is silicon nitride layer 4.

In certain exemplary embodiments, all or some of the MEMS device fabrication steps may be performed at low temperature on top of the complete CMOS wafer 2, thereby leaving the circuitry therein unaffected. Access vias in passivation layer 4 may be left during the CMOS IC design and sacrificial layer 12 is removed over these vias if access to the metal contacts is desired. The exposed metal contacts, such as metal contact 8 are then used to make connections between the MEMS microstructure and the CMOS circuitry in CMOS wafer 2 below.

Microstructure 14 may be composed of any metal, for example, Al, W, Ti, Ta, Cu, Ni, Au, Mo, etc. The selection of material for a particular microstructure layer is dictated by a number of factors including, for example, how much residual stress gradient in the material is acceptable for a particular application, the mass requirement of the structure to meet specific application needs, and the availability of a selective etchant that removes sacrificial material, but which has a low etch rate with respect to silicon nitride passivation layer 4 and microstructure 14.

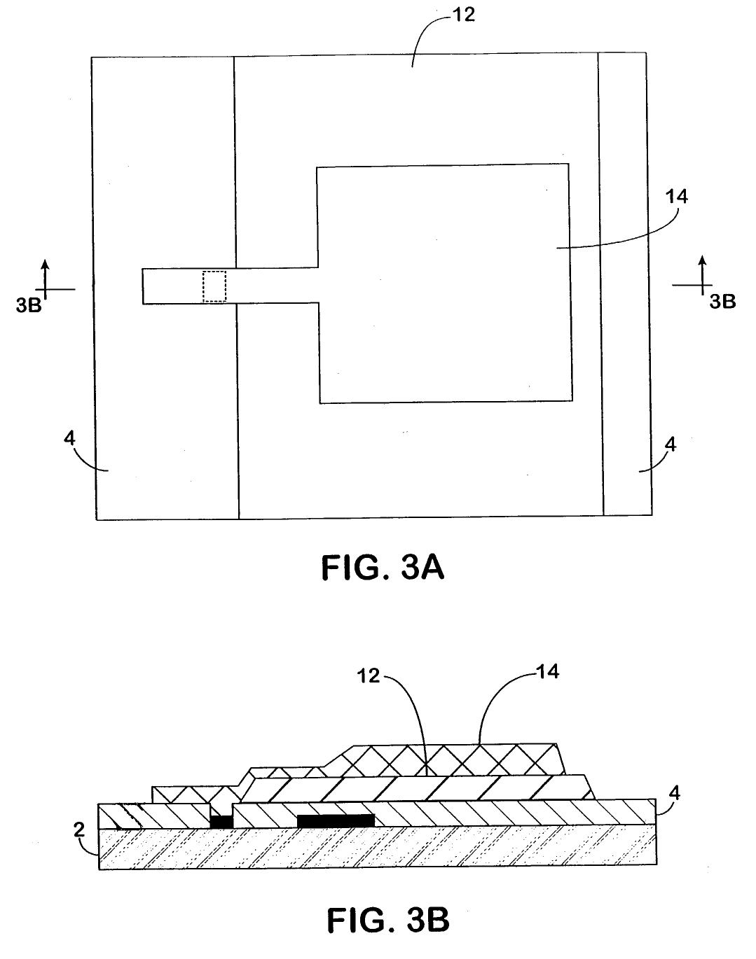

The deposition of the MEMS structural layer is shown in FIGS. 3A and 3B. MEMS microstructure 14 is deposited by prior art methods known to those with ordinary skill in the art, and the undesirable portions are etched away, thereby leaving the desired shape of microstructure 14 behind. Both subtractive and additive methods may be used to create the desired pattern in the microstructure. The top view in FIG. 3A clearly shows the shape of the exemplary microstructure as being a paddle having a long thin beam attached to an anchor point, which in this case is metal contact 8.

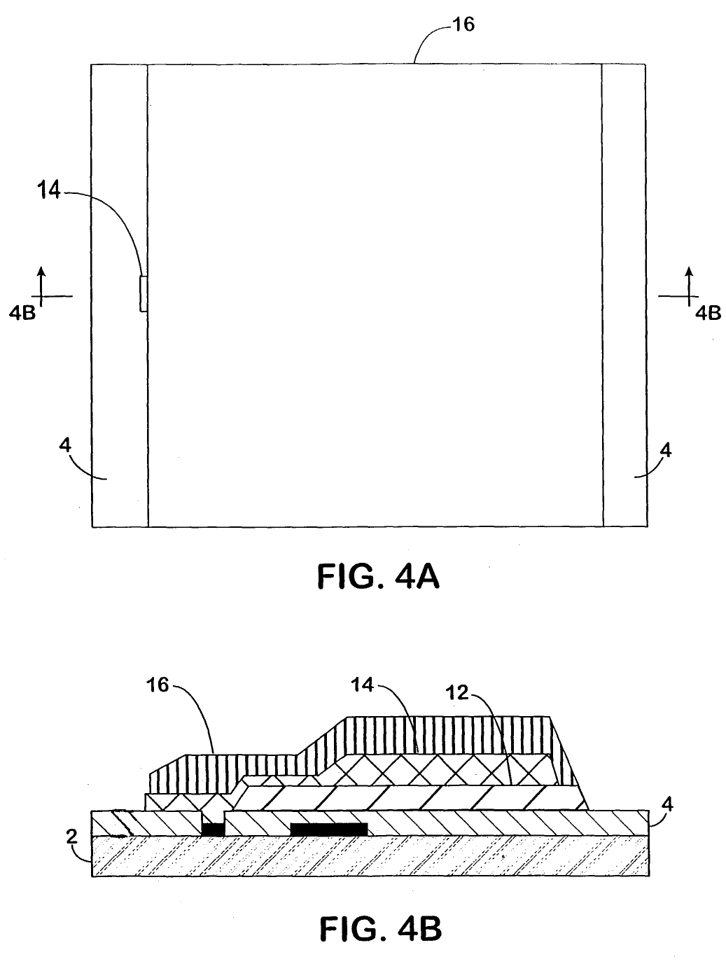

Next, as shown in FIGS. 4A and 4B, a second sacrificial layer 16 may be deposited over microstructure 14. It can be seen from the top view that portions of the second sacrificial layer 16 will come into contact with portions of the bottom sacrificial layer 12, in particular, those areas near the edges of the paddle-shaped main body of the microstructure and those areas on either side of the thin connecting beam portion 15 of the microstructure.

It is preferable that sacrificial layers 12 and 16 be of the same material and in communication with each other, such that when an etchant is introduced, both layers will be etched away without the need to etch additional etchant entry holes. Alternatively, sacrificial layers 12 and 16 may be of different materials, as dictated by the shape and complexity of microstructure 14. Although not necessary in the construction of the exemplary microstructure, more complex microstructures, or multiple microstructures in the same cavity may require etching away of various sacrificial layers at different times, making it necessary to use different materials for the sacrificial layers and different etchants.

One preferred material for sacrificial layers 12 and 16 is photoresist. Photoresist may be chosen because it can be easily etched with an oxygen plasma gas, which is not destructive of microstructure 14, silicon nitride passivation layer 4 or cap layer 18. If sacrificial layers 12 and 16 are of different materials it is possible to etch them separately by selecting an etchant that is selective to one and not the other.

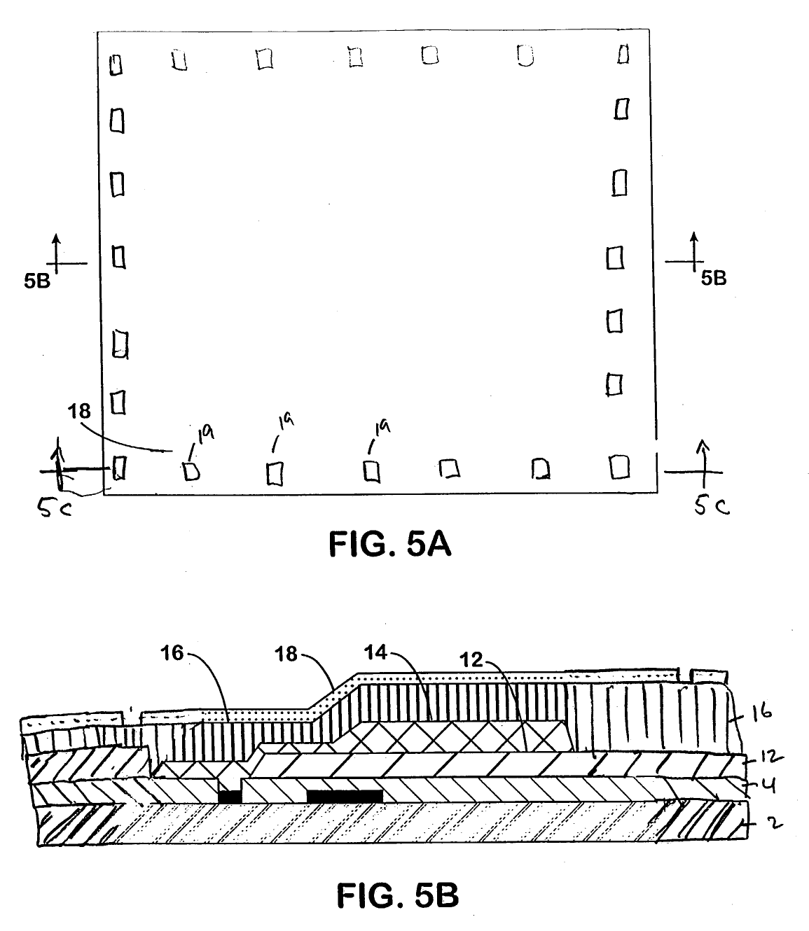

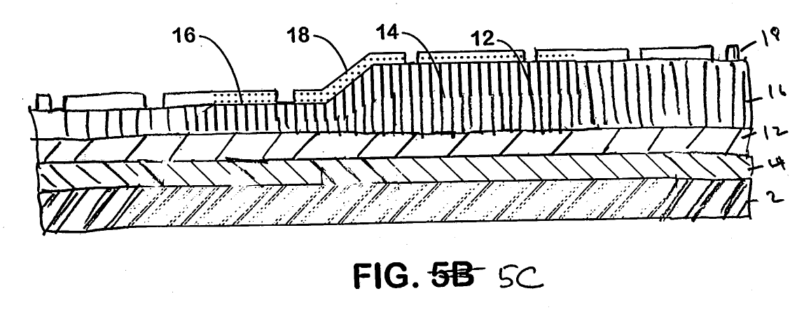

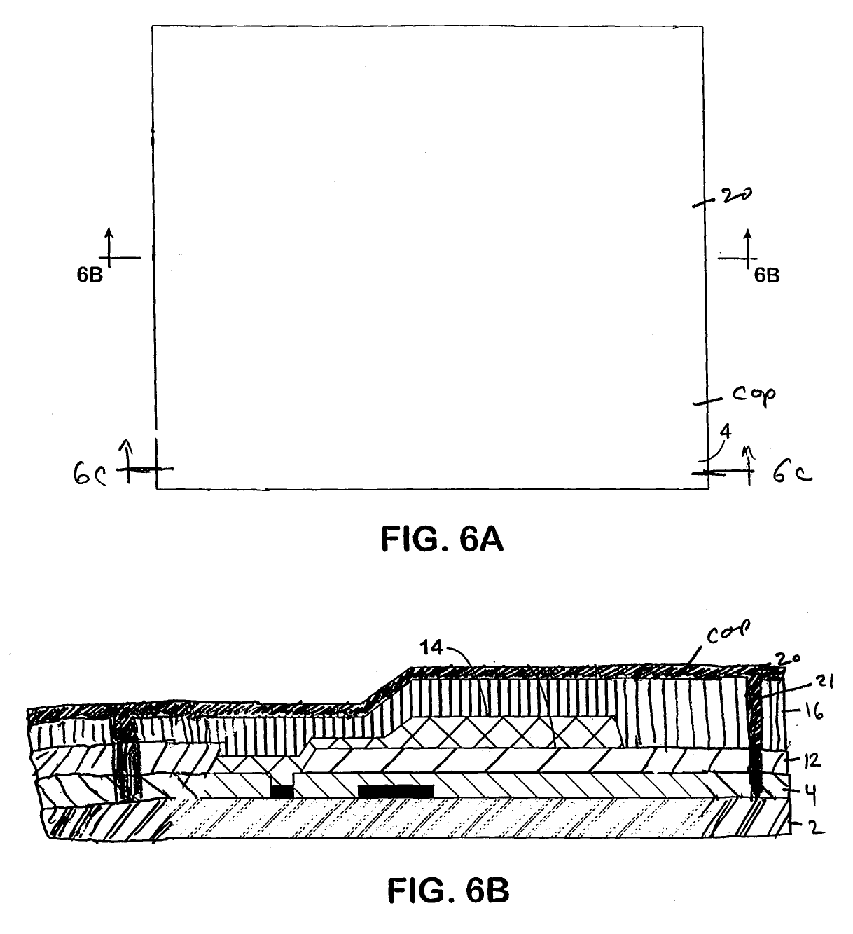

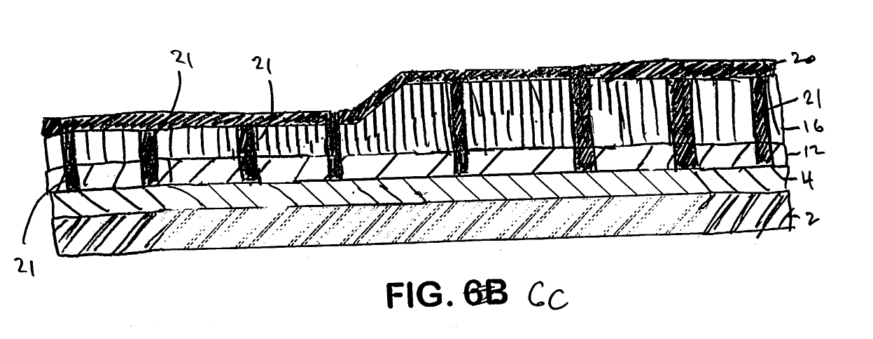

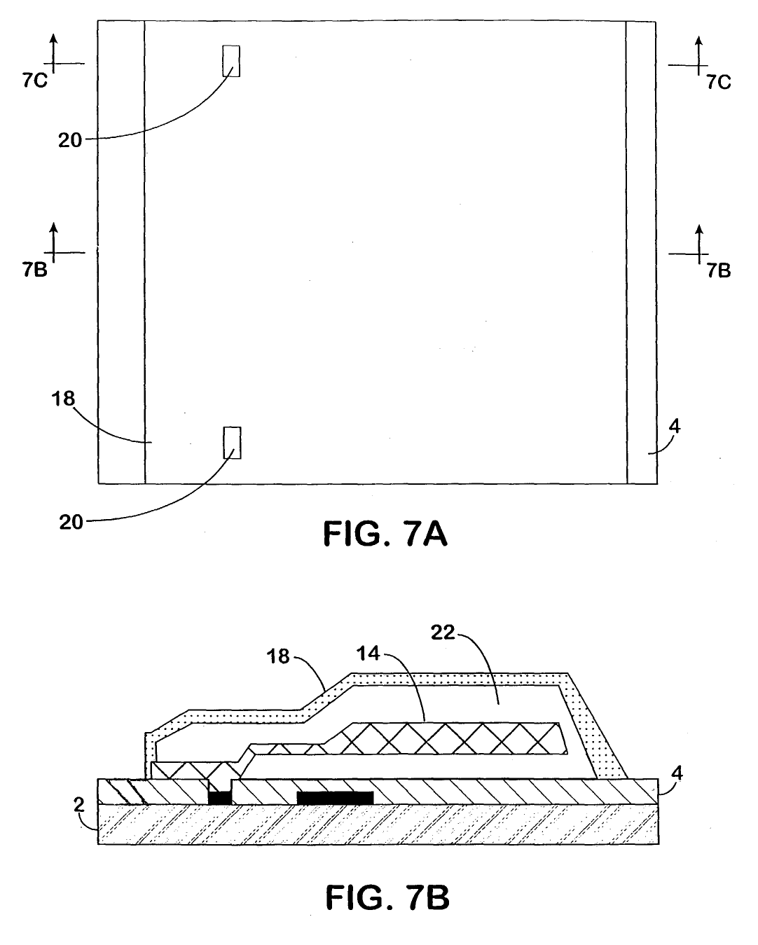

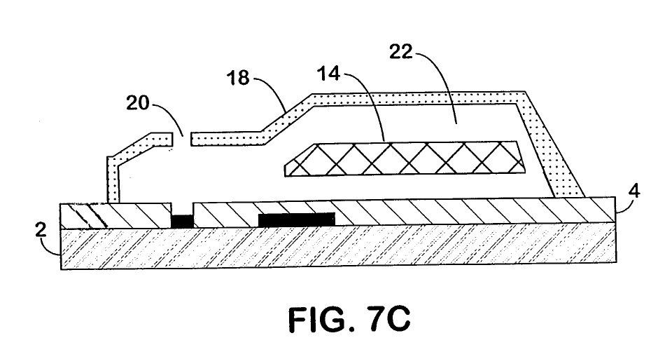

A cap layer 18 is then deposited over the sacrificial layers 12 and 16. The cap layer 18 extends from points on the support surface disposed about the microstructure, and includes a portion overlying the microstructure 14. Cap layer 18 may optionally be applied using standard techniques known in the art, prior to the application of high strength cap overlayers. Cap layer 18, may, for example, be necessary for the operation of microstructure 14, as in the case when cap layer 18 is composed of a metal. An exemplary deposition process for cap layer 18 is shown in FIGS. 5A and 5B. Cap layer 18 may be composed of an insulator or a conductor, depending on the desired electrical operation of the microstructure. Additionally, cap layer 18 must have a low enough residual stress and must be thick enough that it will not buckle after the sacrificial layers 12 and 16 have been removed. In the preferred embodiment, cap layer 18 is composed of the same metal as was chosen for microstructure 14, but, in alternate embodiments, may be composed of any material resistant to the etchant chosen, such as silicon nitride. Cap layer 18 may also be composed of a the same high strength materials user for the layers comprising the cap overlayer, thereby in effect becoming part of the cap overlayer. Cap layer 18 may be patterned and removed to give access to the non-MEMS parts of the integrated circuit. Additionally, etchant access holes or ports 20 may be etched in cap layer 18 to provide access for the introduction of etchant to remove sacrificial layers 12 and 16.

In one embodiment, the cap layer 18 may include a top portion distalmost from the support surface, the top portion ideally extending in a direction substantially parallel to the support surface and a lateral portion extending between the top portion and the support surface. In this embodiment, the etchant access ports 20 may be disposed in the lateral portion of the cap layer 18. Alternatively, the ports may be disposed in the top portion of the cap layer 18, or the substrate may include one or more etchant access ports 20 extending therethrough in a direction substantially transverse to a normal to the support surface of the substrate.

Alternatively, and according to this invention, cap layer 18 may be made from a high strength material as is selected for a high-strength cap overlayer which would be deposited directly on sacrificial layer 16 prior to its removal. In this case cap layer 18 may be composed of a high-strength material selected to provide increased mechanical strength, including increased fracture resistance, hardness, and strain resistance, while concomitantly providing a good seal to the underlying encapsulated microstructure.

Suitable high strength materials for construction of the multilayer cap structure are materials which are ionic bonded, covalently bonded, or mixed ionic and covalently bonded materials and can include, but are not limited to: alumina, silicon carbide, zirconium oxide, titanium oxide, indium tin oxide, zirconium oxide, yttrium stabilized zirconium oxide, titanium nitride, zirconium nitride, cubic boron nitride, aluminum nitride, titanium boride, zirconium boride, titanium carbide, tungsten carbide, vanadium carbide, boron carbide, zirconium carbide, niobium boride, carbide, silicon carbide, strontium titanate, tantalum carbide, cerium oxide, chromium boride, chromium oxide, beryllium oxide, scandium oxide, tungsten and tungsten alloys, magnesium oxide, mullite, diamond, cordierite, ferrite and garnet.

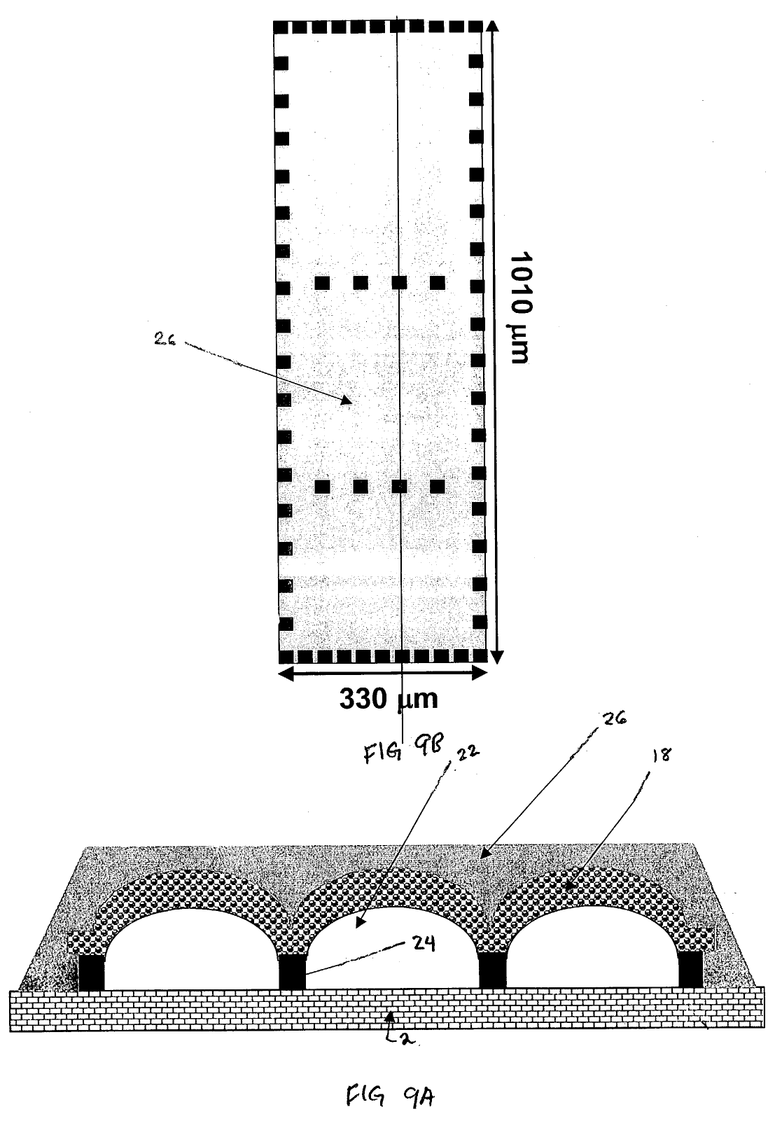

Alternatively, the device may be set up such that no etching of etchant access holes is necessary. Instead, cap layer 18 may be supported by pillars, and the etchant access can be achieved through the etching away of sacrificial material between the pillars, as shown in FIGS. 9A and 9B.

Once all of the sacrificial material has been etched away from under cap layer 18, whether it be silicon nitride, alumina, or another high-strength material, microstructure 14 is able to move within cavity 22 previously occupied by sacrificial layers 12 and 16, with beam 15 acting as a spring and contact pad 8 acting as an anchor point.

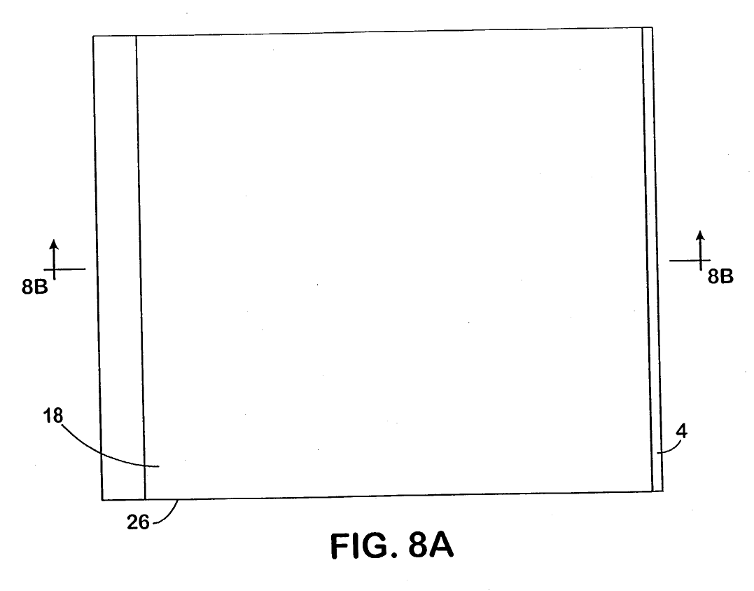

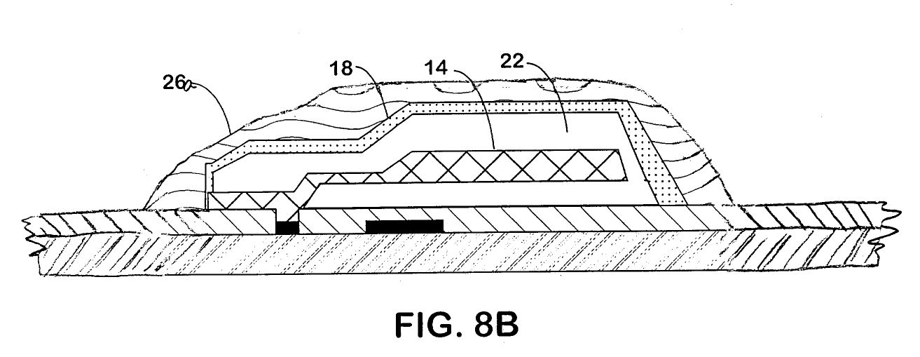

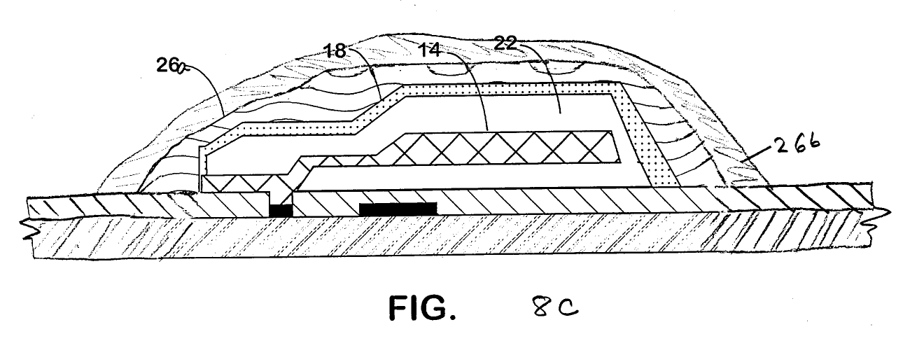

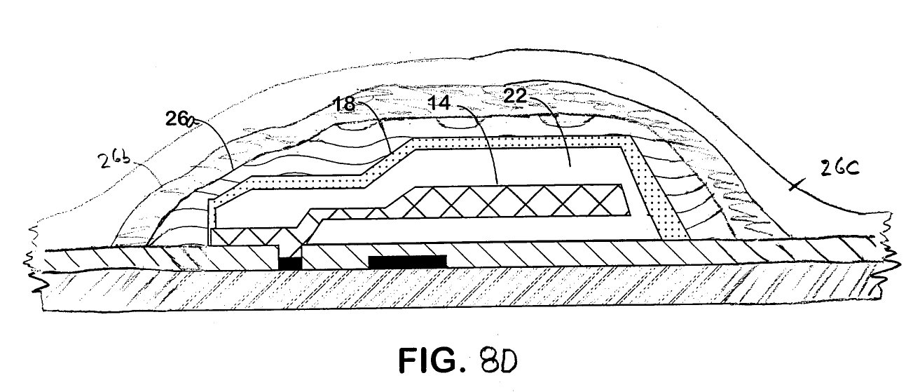

As shown in FIGS. 8A-8D, cap overlayer 26 may be applied in multiple layers under varying conditions to improve the characteristics of the deposition. In other words, in a preferred embodiment, cap overlayer 26 is a multilayer structure having an innermost layer contiguous with cap layer 18. In the example herein, three layers, 26a-26c are shown. Each of the multiple layers forming cap overlayer 26 may be applied by a traditional sputtering process, or by other known deposition processes. In certain exemplary embodiments, one or more of the multiple layers forming cap overlayer 26 may be deposited under varying deposition conditions. For example, for the first layer 26a, shown in FIG. 8B, the pressure may be in the range of 2-100 mT, with 30 mT being an optimal value.

In one embodiment, the cap overlayer 26 may be a graded density structure, having a relatively high density region contiguous with the cap layer. It has been found that the application of a bias voltage during the deposition process tends to smooth the surface of the layer being applied. Therefore, it is desirable that the first cap layer be applied using a bias voltage to avoid the formation of voids where cap layer 26a overlays any sharp corners in the underlying structure. The exact bias voltage applied will vary, depending upon the sputtering machine being used for the deposition. For example, it has been found that, when using a model 620B machine manufactured by Comptech, a bias voltage of about 180v at a pressure of about 30 mTorr produces the desired characteristics. Therefore, with this particular machine, the power may be approximately 0.5-10 watts/cm2, and the bias voltage may be about 90-200v.

Preferably, the sputtering deposition apparatus uses an RF generated plasma (preferably derived from an inert gas such as argon) between a first electrically conductive plate supporting a material-to-be-deposited, such as aluminum oxide, and a second electrically conductive plate supporting the substrate upon which the material is to be deposited. A bias voltage, preferably a relatively high bias voltage, is established between the first and second plates to preferentially accelerate ions in the plasma toward the second plate, with the result that relatively low energy ion bombardment at the material-to-be-deposited effects a relatively low rate sputtering of the material which is deposited on the substrate, and relatively high energy ion bombardment at the substrate knocks off loosely bound deposited material therefrom. As a consequence, a relatively dense, stable deposited layer is formed on the substrate.

It has been found that the use of the relatively high bias voltage tends to reduce the “shadowing” effect caused by sharp corners on cap layer 18 or on the uppermost layer of sacrificial material 16, depending upon which layer the innermost cap overlayer 26a is applied. In the application of the second high-strength layer 26b, shown in FIG. 8C, the bias voltage may be eliminated. This tends to even out the thickness of the layer. The third layer 26c may then be applied, again using a 90v-200v bias. The combination of the pressure and the varying bias voltages as each layer is applied tends to make the overall cap more conformal and helps to eliminate intrinsic stress in the high strength material, which, if great enough, could cause the cap structure to pull away from the base of the wafer. Preferably, the intrinsic stress gradient of the multi-layer cap is at or near zero around the perimeter of the cap, where the cap meets the substrate layer 2.

In the event that the first high-strength layer has been deposited directly over a sacrificial layer, the second layer of high-strength material will also serve to seal any etchant access holes, regardless of whether the holes were etched into the first layer of high-strength material, or were formed naturally between pillars supporting the first cap layer.

One skilled in the art will appreciate that, although the exemplary embodiment described above includes a three layer cap, cap 26 may comprise any number of layers.

In certain exemplary embodiments, the layers of the cap overlayer 26 and the cap layer 18, may be deposited at a temperature selected to minimize thermal damage to the underlying microstructure. For example, a layer of the cap overlayer 26 or the inner cap layer 18 may be deposited at a temperature less than 125° C., or, in some embodiments, less than 100° C.

The one or more layers of the cap overlayer 26, or the inner cap layer 18, may also be deposited at a low pressure in the presence of an inert gas, such as argon or other noble gases, for the purpose of sealing the gas inside of the cavity with the microstructure. For example, cap overlayer 26 may be deposited in a vacuum chamber at a low pressure of less than 10 mT, sufficient to facilitate deposition, in an argon environment. As a result, the cavity formed by the cap can be sealed to create a low pressure, inert environment about the microstructure. Additional layers, including all subsequent layers of cap overlayer 26, may be deposited at higher pressures in the presence of alternative gases.

It may or may not, dependent upon the topology of the wafer and the microstructure, be possible to obtain a sufficiently good seal around the inner chamber with the multiple layers of alumina or other high-strength material comprising layers 26a, 26b and 26c. Therefore, in an additional embodiment of the invention, an additional layer of thin material that acts as a good barrier, preferably silicon nitride, may be deposited over the outermost layer of cap overlayer 26, thereby providing an improved seal to the chamber containing the microstructure.

The multi-layer approach has the advantage of being able to build up a relatively thick layer of material that is extremely strong and resistant to damage from environmental forces. Ideally, the cumulative layers of the high-strength cap overlayer may be between 5 and 50 microns in thickness, depending upon the area of the wafer which is being encapsulated. The process disclosed herein should produce a cap which is able to withstand a pressure in the range of 600-3000 psi at temperatures of up to 300 degrees C., as would typically be encountered during the plastic injection molding process. Additionally, the cap produced by this process should be rigid enough and should have adhesion with the wafer sufficient to withstand a uniform pressure equivalent to 60 atmospheres without any portion of the cap structure being deflected by more than one micron from its original position.

A simple microstructure that could be utilized as a Z-axis accelerometer has been described to show the general process of creating a microstructure in a sealed cavity having a high-strength, rigid cap. However, as will be realized by one of ordinary skill in the art, and as contemplated by the inventors, the process may be used to build microstructures of more complexity, involving many combinations of sacrificial and structural layers. It is also contemplated that movable structures consisting of many layers of stacked sacrificial and structural materials are within the scope of this invention.

Lastly, the figures showing the process are not to scale and should not be construed as limitations on the process in this respect. Note that the term “sealed cavity” as used herein is meant to denote a cavity which has no openings, but which is not necessarily hermetically sealed.

We claim:

1. A method of creating a sealed cavity on a wafer comprising the steps of:
depositing one or more layers of a sacrificial material on said wafer and shaping said sacrificial material;
depositing a first cap layer on said one or more layers of sacrificial material;
removing said one or more layers of sacrificial material such that said first cap layer and the portion of said wafer underlying said first cap layer define said cavity; and
depositing one or more additional cap layers on said first cap layer, said one or more additional cap layers being formed of a high strength material:
wherein said one or more additional cap layers contact said wafer.

2. The method of claim 1 wherein said high strength material is selected from a group comprising ionic bonded materials covalently bonded material and or mixed ionic and covalent bonded materials.

3. The method of claim 1 wherein said deposited high strength material can withstand pressures above 600 psi and temperatures up to 300 degrees C. when the total thickness of all deposited layers is less than approximately 50 microns.

4. The method of claim 1 wherein said deposited high-strength material can withstand a uniform pressure of up to 60 atmospheres without deflecting more than one micron from its original position.

5. The method of claim 1 wherein said high strength material is alumina.

6. The method of claim 1 wherein said step of removing said one or more layers of said sacrificial material comprises the steps of:
creating one or more etchant access holes in said first cap layer; and
introducing etchant to said one or more sacrificial layers through said one or more access holes.

7. The method of claim 1 wherein said step of removing said one or more layers of said sacrificial material comprises the steps of:
creating a plurality of pillars through said one or more layers of sacrificial material; and
depositing said first cap layer such that first cap layer is supported by said plurality of pillars after said sacrificial material is removed.

8. The method of claim 1 further comprising the step of removing a portion of the surface of said wafer, such that said wafer is a non-planar surface, wherein the non-planar area of said wafer and said high strength cap layers define said cavity.

9. The method of claim 1 wherein at least one of said high strength layers is deposited in a sputtering machine in the presence of a bias voltage.

10. The method of claim 9 wherein said one or more high strength layers have a relatively low intrinsic stress gradient and good adhesion at the boundary between said one or more layers of high strength material and said wafer.

11. The method of claim 10 wherein said step of depositing one or more overlayers of a high strength material further comprises the steps of:
depositing a first layer of high strength material in the presence of a bias voltage; and
depositing one or more additional layers of relatively high strength material.

12. The method of claim 11 wherein said step of depositing one or more additional layers of high strength material further comprises the steps of:
depositing a second layer of high strength material with no bias voltage; and
depositing a third layer of high strength material in the presence of a bias voltage.

13. The method of claim 1 wherein said one or more layers of high strength material are deposited by sputtering at a pressure in the range of 2 mTorr to 100 mTorr.

14. The method of claim 12 wherein said one or more layers of high strength material are deposited under a pressure of 30 mTorr.

15. The method of claim 1 wherein said first cap layer is deposited at a relatively low pressure in the presence of an inert gas, such that said sealed cavity is filled with said inert gas at a pressure of 10 mT or less.

16. The method of claim 1 wherein said first cap layer is also composed of a high strength material.

17. The method of claim 1 wherein said high strength material is selected from a group comprising alumina, titanium oxide, indium tin oxide, zirconium oxide, yttrium stabilized zirconium oxide, titanium nitride, zirconium nitride, cubic boron nitride, aluminum nitride, titanium boride, zirconium boride, titanium carbide, tungsten carbide, vanadium carbide, boron carbide, zirconium carbide, niobium boride, carbide, silicon carbide, strontium titanate, tantalum carbide, cerium oxide, chromium boride, chromium oxide, beryllium oxide, scandium oxide, tungsten and tungsten alloys, magnesium oxide, mullite, diamond, cordierite, ferrite and garnet.

18. The method of claim 1 further comprising the step of depositing an additional layer of material over the outermost of said layers of high strength material.

19. The method of claim 18 wherein said additional layer is composed of silicon nitride.

20. The method of claim 1 further comprising the step of forming a microstructure within said sealed cavity.

21. A micro-sealed cavity comprising:
a wafer;
a cap structure covering at least a portion of said wafer, said cap structure contacting said wafer to define a cavity thereunder;
wherein said cap structure is composed of a high strength material.

22. The micro-sealed cavity of claim 21 wherein said high strength material is selected from a group comprising ionic bonded materials, covalently bonded material and or mixed ionic and covalent bonded materials.

23. The micro-sealed cavity of claim 21 wherein said cap structure can withstand pressures above 600 psi and temperatures up to 300 degrees C. when the total thickness of all deposited layers is less than approximately 50 microns.

24. The micro-sealed cavity of claim 21 wherein said cap structure can withstand a uniform pressure of up to 60 atmospheres without deflecting more than one micron from its originals position.

25. The micro-sealed cavity of claim 21 wherein said high strength material is alumina.

26. The micro-sealed cavity of claim 21 wherein said cap structure comprises one or more layers of said high strength material.

27. The micro-sealed cavity of claim 26 wherein said cap structure is a multi-layered stricture and further wherein at least one of said layers of said multi-layered structure was deposited in the presence of a bias voltage.

28. The micro-sealed cavity of claim 27 wherein said cap structure comprises:
a first layer of high strength material deposited in the presence of a bias voltage;
a second layer of high strength material deposited with no bias voltage; and
a third layer of high strength material deposited in the presence of a bias voltage.

29. The micro-sealed cavity of claim 26 wherein said one or more layers of high strength material are deposited under a pressure in the range of 2 mTorr to 100 mTorr.

30. The micro-sealed cavity of claim 29 wherein said one or more layers of high strength material are deposited under a pressure of 30 mTorr.

31. The micro-sealed cavity of claim 21 wherein said first layer of high strength material is deposited at a low pressure in the presence of an inert gas, such that said micro-sealed cavity is filled with said inert gas at a pressure of 10 mTorr or less.

32. The micro-sealed cavity of claim 21 wherein said cap structure has a low intrinsic stress gradient and good adhesion to said wafer at the point of contact between said cap structure and said wafer.

33. The micro-sealed cavity of claim 27 wherein said cap structure has a low intrinsic stress gradient and good adhesion to said wafer at the point of contact between said cap structure and said wafer.

34. The micro-sealed cavity of claim 21 wherein said high strength material is selected from a group comprising alumina, titanium oxide, indium tin oxide, zirconium oxide, yttrium stabilized zirconium oxide, titanium nitride, zirconium nitride, cubic boron nitride, aluminum nitride, titanium boride, zirconium boride, titanium carbide, tungsten carbide, vanadium carbide, boron carbide, zirconium carbide, niobium boride, carbide, silicon carbide, strontium titanate, tantalum carbide, cerium oxide, chromium boride, chromium oxide, beryllium oxide, scandium oxide, tungsten and tungsten alloys, magnesium oxide, mullite, diamond, cordierite, ferrite and garnet.

35. The micro-sealed cavity of claim 21 further comprising an additional layer deposited on the outermost layer of high strength material, said additional layer providing a seal of said micro-sealed cavity.

36. The micro-sealed cavity of claim 35 wherein said additional layer is composed of silicon nitride.

37. The micro-sealed cavity of claim 21 further comprising a microstructure defined within said micro-sealed cavity.

38. In a wafer for containing a microstructure, an improvement comprising:
depositing one or more layers of high strength material over said microstructure to define a cavity between said wafer and said one or more layers of high strength material.

39. The improvement of claim 38 wherein said one or more layers of high strength material are deposited directly on a layer of sacrificial material, said sacrificial material being subsequently removed.

40. The improvement of claim 39 wherein said one or more layers of high strength material are deposited by a method comprising the steps of:
depositing a first layer of high strength material over said sacrificial material;
removing said sacrificial material; and
optionally depositing one or more subsequent layers of high strength material over said first layer of high strength material.

41. The improvement of claim 40 wherein said first layer of high strength material is supported on said wafer and wherein said step of removing said sacrificial material comprises the steps of:
etching one or more holes in said first layer of high strength material through which an etching agent is introduced to etch away said sacrificial material;
wherein said one or more subsequent layers of high strength material serve to seal said one or more holes in said first layer of high strength material.

42. The improvement of claim 38 wherein said high strength material is selected from a group comprising ionic bonded materials, covalently bonded material and or mixed ionic and covalent bonded materials.

43. The improvement of claim 38 wherein said high strength material is selected from a group comprising alumina, titanium oxide, indium tin oxide, zirconium oxide, yttrium stabilized zirconium oxide, titanium nitride, zirconium nitride, cubic boron nitride, aluminum nitride, titanium boride, zirconium boride, titanium carbide, tungsten carbide, vanadium carbide, boron carbide, zirconium carbide, niobium boride, carbide, silicon carbide, strontium titanate, tantalum carbide, cerium oxide, chromium boride, chromium oxide, beryllium oxide, scandium oxide, tungsten and tungsten alloys, magnesium oxide, mullite, diamond, cordierite, ferrite and garnet.

44. The improvement of claim 38 wherein said high strength material is alumina.

45. The improvement of claim 38 wherein said one or more layers of high strength material can withstand pressures above 600 psi and temperatures up to 300 degrees C. when the total thickness of all deposited layers is less than approximately 50 microns.

46. The improvement of claim 38 wherein said one or more layers of high strength material can withstand a uniform pressure of up to 60 atmospheres without deflecting more than one micron from its original position.

47. The improvement of claim 38 further comprising a seal layer over the outermost layer of said high-strength material.

48. The improvement of claim 47 where said seal layer is composed of silicon nitride.

49. The improvement of claim 40 wherein said first layer of high strength material is supported on said wafer by a plurality of pillars formed through said sacrificial material and wherein said step of removing said sacrificial material comprises the steps of:
exposing said wafer to an etching agent;
allowing said etching agent to etch away said sacrificial material between said plurality of pillars, thereby forming access vias through which said etching agent can etch said sacrificial material disposed under said first layer of high strength material;
wherein said one or more subsequent layers of high strength material serve to seal said access vias formed between said plurality of pillars.

50. The improvement of claim 40 wherein said first layer of high strength material is deposited in the presence of a first bias voltage.

51. The improvement of claim 50 wherein said first bias voltage is approximately 90-200 volts.

52. The improvement of claim 50 wherein a second layer of high strength material is deposited with no bias voltage.

53. The improvement of claim 52 wherein a third layer of high strength material is deposited in the presence of a second bias voltage.

54. The improvement of claim 53 wherein said second bias voltage is approximately 90200 volts.

55. The improvement of claim 40 wherein all layers of high strength material are deposited under a pressure in the range of 2 mTorr to 100 mTorr.

56. The improvement of claim 55 wherein all layers of high strength material are deposited under a pressure of approximately 30 mTorr.

57. The improvement of claim 40 wherein said first layer of said one or more subsequent layers of high-strength material is deposited at a low pressure in the presence of an inert gas, such that said micro-sealed cavity is filled with said inert gas at a pressure of 10 mTorr or less.

58. The improvement of claim 38 wherein said one or more layers or high strength material are deposited on a cap layer, said cap layer defining said cavity.

59. The improvement of claim 58 wherein said one or more layers of high strength material are deposited by a method comprising the steps of:
removing said sacrificial material; and
depositing one or more layers of high strength material over said cap layer.

60. The improvement of claim 59 wherein said cap layer is supported on said wafer and wherein said step of removing said sacrificial material comprises the steps of:
etching one or more holes in said cap layer through which an etching agent is introduced to etch away said sacrificial material;
wherein said one or more subsequent layers of high strength material seal said one or more holes in said cap layer.

61. The improvement of claim 59 wherein said cap layer is supported on said wafer by a plurality of pillars formed through said sacrificial material and wherein said step of removing said sacrificial material comprises the steps of:
exposing said wafer to an etching agent;
allowing said etching agent to etch away said sacrificial material between said plurality of pillars, thereby forming access vias through which said etching agent can etch said sacrificial material disposed under said cap layer;
wherein said one or more layers of high strength material serve to seal said access vias formed between said plurality of pillars.

62. The improvement of claim 58 wherein said cap layer is composed of a material selected from the group comprising silicon nitride and aluminum.

63. The improvement of claim 59 wherein said step of depositing one or more layer of high strength material comprises the steps of:
depositing a first layer of high strength material in the presence of a first bias voltage;
depositing a second layer of high strength material; and
depositing a second layer of high strength material in the presence of a second bias voltage.

64. The improvement of claim 63 wherein said first bias voltage is approximately 90-200 v and said second bias voltage is approximately 50-100v.

65. The improvement of claim 59 wherein said one or more layers of high strength material are deposited under a pressure in the range of 2 mTorr to 100 mTorr.

66. The improvement of claim 65 wherein said one or more layers of high strength material are deposited under a pressure of approximately 30 mTorr.

67. The improvement of claim 59 wherein the first layer of said one or more layers of high-strength material is deposited at a low pressure in the presence of an inert gas, such that said micro-sealed cavity is filled with said inert gas at a pressure of 10 mTorr or less.

68. A method of fabricating an encapsulated micromachined assembly, comprising the steps of:
providing a substrate;
depositing a first layer of sacrificial material on said substrate;
forming a microstructure of a desired shape on said first layer of sacrificial material;
depositing a second layer of sacrificial material on said first layer of sacrificial material, said second layer covering said microstructure;
depositing a first cap layer on top of said first and said second layers of sacrificial material;
removing said first and said second layers of sacrificial materials; and
depositing one or more additional cap layers on top of said first cap layer, said one or more additional cap layers being formed of a high strength material having a relatively high stiffness.

69. The method of claim 61 wherein said material forming said first cap layer is also characterized by a relatively high stiffness.

70. The method of claim 68 further comprising the step of depositing a seal layer over the outermost one of said one or more additional cap layers.

71. The method of claim 68 wherein said material having a relatively high stiffness is selected from a group comprising ionic bonded materials, covalently bonded material and or mixed ionic and covalent bonded materials.

72. The method of claim 68 wherein said one or more cap layers can withstand pressures above 600 psi and temperatures up to 300 degrees C. when the total thickness of all deposited cap layers is less than approximately 50 microns.

73. The method of claim 68 wherein said one or more cap layers can withstand a uniform pressure up to 60 atmospheres without deflecting more than one micron from its original position.

74. A MEMS device comprising:
a substrate;
a microstructure formed on said substrate;
a cap covering said microstructure; and
one or more additional layers of high strength material covering said cap.

75. The MEMS device of claim 74 wherein said one or more layers of high strengftgh material is composed of a material characterized by a relatively high stiffness.

76. The MEMS device of claim 74 wherein the first layer of high strength material is deposited in the presence of a first bias voltage.

77. The MEMS device of claim 66 wherein the second layer of high strength material is deposited in the absence of a bias voltage.

78. The MEMS device of claim 77 where the third layer of high strength material is deposited in the presence of a second bias voltage.

79. The MEMS device of claim 78 further comprising an outer seal layer, said outer seal layer covering the outermost layer of high-strength material.

80. The MEMS device of claim 78 wherein said high strength material is selected from a group comprising ionic bonded materials, covalently bonded material and or mixed ionic and covalent bonded materials.

81. The MEMS device of claim 78 wherein said one or more layers of high strength material can withstand pressures above 600 psi and temperatures up to 300 degrees C. when the total thickness of all deposited layers is less than approximately 50 microns.

82. The MEMS device of claim 78 wherein said one or more layers of high-strength material can withstand a uniform pressure of unto 60 atmospheres without deflecting more than one micron from its original position.

83. A micromachined assembly comprising:
a substrate having a support surface on one side and a base surface on a side opposite said support surface;
a cap layer extending from points on said support surface disposed about a region of interest on said support surface and including a portion overlying said region of interest;
a cap overlayer extending from said support surface and disposed over and contiguous with said cap layer;
whereby said cap layer and said cap overlayer and said support surface define a closed capsule about an interior region containing said region of interest; and
wherein said cap overlayer is characterized by a relatively high stiffness with respect to said cap layer.

84. A micromachined assembly according to claim 83, wherein said cap layer combined with said cap overlayer is characterized by a relatively high stiffness with respect to said cap layer.

85. A micromachined assembly according to claim 84, wherein said relatively high stiffness of said cap layer combined with said cap overlayer is sufficient to allow said cap layer and said cap overlayer to withstand a uniform pressure of up to about 60 atmospheres, without any portion of said cap layer and said cap overlayer deflecting more than one micron compared to their original position.

86. A micromachined assembly according to claim 83, wherein said cap layer and said cap overlayer comprises a thin film that is deposited onto said substrate from a gaseous state.

87. A micromachined assembly according to claim 83 wherein said support surface is substantially planar.

88. A micromachined assembly according to claim 83 further comprising a micro structure disposed on said region of interest of said support surface.

89. A micromachined assembly according to claim 88 wherein said microstructure is a micro-electro-mechanical system (MEMS).

90. A micromachined assembly according to claim 88 wherein said microstructure is a SAW (surface acoustic wave) device.

91. A micromachined assembly according to claim 88, wherein said microstructure is a Film Bulk Acoustic Resonator.

92. A micromachined assembly according to claim 88, wherein said microstructure is a capacitive sense plate adapted to measure ambient pressure due to a variation in the spacing between said support surface and the inner surface of said cap layer.

93. A micromachined assembly according to claim 88 wherein said microstructure is an integrated circuit (IC).

94. A micromachined assembly according to claim 83 wherein said cap layer includes a top portion distalmost from said support surface, said top portion extending in a direction substantially parallel to said support surface;
and wherein said cap layer includes a lateral portion extending between said top portion and said support surface.

95. A micromachined assembly according to claim 83 wherein said cap layer includes one or more ports extending therethrough in a direction substantially transverse to a normal to said support surface.

96. A micromachined assembly according to claim 95 wherein said cap overlayer is disposed within said one or more ports.

97. A micromachined assembly according to claim 95 wherein said cap overlayer is disposed over and around said one or more ports.

98. A micromachined assembly according to claim 95, wherein said cap layer includes:
a top portion distalmost from said support surface, said top portion extending in a direction substantially parallel to said support surface; and
a lateral portion extending between said top portion and said support surface; and
wherein said ports are disposed in said lateral portion of said cap layer.

99. A micromachined assembly according to claim 95, wherein said cap layer includes a top portion distalmost from said device support surface, said top portion extending in a direction substantially parallel to said device support surface; and
wherein said ports are disposed in said top portion of said cap layer.

100. A micromachined assembly according to claim 83, wherein said interior region is substantially filled with a noble gas.

101. A micromachined assembly according to claim 100, wherein said noble gas is at a pressure in the approximate range 0.01-10 Torr.

102. A micromachined assembly according to claim 83, wherein said cap overlayer is a multilayer structure having an innermost layer contiguous with said cap layer.

103. A micromachined assembly according to claim 102, wherein at least the lowermost layer within said multilayer structure is a relatively high energy RF sputtered material.

104. A micromachined assembly according to claim 103, wherein at least two adjacent layers of said cap overlayer are alumina layers.

105. A micromachined assembly according to claim 104 wherein said adjacent alumina layers have material characteristics corresponding to laydown under different conditions.

106. A micromachined assembly according to claim 104 wherein at least one of said adjacent alumina layers comprises an RF-sputtered alumina layer.

107. A micromachined assembly according to claim 83 wherein said cap overlayer is a graded density structure having a relatively high density region contiguous with said cap layer.

108. A micromachined assembly according to claim 107 wherein said cap overlayer is a relatively high energy sputtered material.

109. A micromachined assembly according to claim 108, wherein said relatively high energy sputtered material is selected from a group comprising alumina, titanium oxide, indium tin oxide, zirconium oxide, yttrium stabilized zirconium oxide, titanium nitride, zirconium nitride, cubic boron nitride, aluminum nitride, titanium boride, zirconium boride, titanium carbide, tungsten carbide, vanadium carbide, boron carbide, zirconium carbide, niobium boride, carbide, silicon carbide, strontium titanate, tantalum carbide, cerium oxide, chromium boride; chromium oxide, beryllium oxide, scandium oxide, tungsten and tungsten alloys, magnesium oxide, mullite, diamond, cordierite, ferrite and garnet.

110. A micromachined assembly according to claim 83 wherein said substrate is a CMOS structure with said device support surface being a passivation layer, and includes CMOS circuit devices defined within said substrate between said device support surface and said base surface.

111. A micromachined assembly according to claim 83 wherein said substrate includes one or more ports extending therethrough in a direction substantially transverse to a normal to said support surface.

112. A micromachined assembly, comprising:
a substrate having a support surface on one side and a base surface on a side opposite said support surface;
a microstructure disposed on said support surface;
a sputter-deposited cap layer extending from points on said support surface and disposed over at least a portion of said microstructure, said cap layer and said device support surface defining a capsule about an interior region containing said microstructure, said cap layer being formed of a material characterized by a relatively high stiffness.

113. A micromachined assembly according to claim 112 wherein said microstructure is a micro-electro-mechanical system (MEMS).

114. A micromachined assembly according to claim 112 wherein said microstructure is at least one of a micro-electro-mechanical system (MEMS), a SAW (surface acoustic wave) device, a Film Bulk Acoustic Resonator, an integrated circuit (IC), and a capacitive sense plate adapted to measure ambient pressure due to a variation in the spacing between said substrate and the inner surface of said cap layer.

115. A micromachined assembly according to claim 112 wherein said cap layer includes one or more ports extending therethrough in a direction transverse to a normal to said support surface.

116. A micromachined assembly according to claim 112, wherein said cap layer is a multilayer structure having an innermost layer contiguous with said cap layer.

117. A microstructure comprising:
a wafer,
a cap, said cap contacting said wafer around a closed perimeter to define a cavity between said wafer and said cap;
wherein said cap is composed of a plurality of layers.

118. The microstructure of claim 117 wherein individual ones of said plurality of layers in said cap are composed of different materials.

119. The microstructure of claim 117 wherein individual ones of said layers in said cap have been deposited under one or more different deposition parameters.

120. The microstructure of claim 119 wherein said deposition parameters are selected from a group consisting of temperature, bias voltage and pressure in a sputter deposition apparatus.

121. The microstructure of claim 119 wherein the first of said plurality of layers to be deposited is deposited using said parameters selected to result in a relatively strong adhesion between said first layer and said wafer.

122. The microstructure of claim 119 wherein said plurality of layers is deposited using said parameters selected to promote conformity from layer to layer.

123. The microstructure of claim 122 wherein at least one of said layers are deposited in the presence of a relatively high bias voltage between a sputter source and said wafer.

124. The microstructure of claim 117 wherein the first of said plurality of layers to be deposited is deposited over a layer of sacrificial material, said sacrificial material being subsequently removed.

125. The microstructure of claim 117 wherein said plurality of layers have been sputter deposited.

126. The microstructure of claim 117 wherein at least one layer of said plurality of layers is composed of a material selected from a group comprising ionic bonded materials, covalently bonded materials and mixed ionic and covalently bonded materials.

127. The microstructure of claim 117 wherein at least one layer of said plurality of cap layers is composed of a relatively high strength material selected from a group comprising alumina, titanium oxide, indium tin oxide, zirconium oxide, yttrium stabilized zirconium oxide, titanium nitride, zirconium nitride, cubic boron nitride, aluminum nitride, titanium boride, zirconium boride, titanium carbide, tungsten carbide, vanadium carbide, boron carbide, zirconium carbide, niobium boride, carbide, silicon carbide, strontium titanate, tantalum carbide, cerium oxide, chromium boride, chromium oxide, beryllium oxide, scandium oxide, tungsten and tungsten alloys, magnesium oxide, mullite, diamond, cordierite, ferrite and garnet.

128. The microstructure of claim 117 wherein said cap can withstand pressures above 600 psi and temperatures up to 300 degrees C. when the total thickness of said plurality of layers is less than approximately 50 microns.

129. The microstructure of claim 117 wherein said cap can withstand a uniform pressure of up to 60 atmospheres without deflecting more than one micron from its original position.

130. The microstructure of claim 117 further comprising a micro-electro-mechanical device disposed in said cavity.

131. A method of creating a sealed micro cavity on a wafer comprising the steps of:
depositing one or more layers of a sacrificial material on said wafer;
depositing a plurality of cap layers over said sacrificial material, said individual ones of said plurality of cap players being defined by a change in one or more deposition parameters or a change in material between one layer and the next.

132. The method of claim 131 further comprising the step of removing said sacrificial material.

133. The method of claim 131 wherein said deposition parameters are selected from a group comprising temperature, bias voltage and pressure.

134. The method of claim 133 wherein at least one of said layers is deposited using a high bias voltage.

135. The method of claim 131 wherein at least one layer of said plurality of cap layers is composed of a material selected from a group comprising ionic bonded materials, covalently bonded materials and mixed ionic and covalently bonded materials.

136. The improvement of claim 131 wherein at least one layer of said plurality of cap layers is composed of a high strength material selected from a group comprising alumina, titanium oxide, indium tin oxide, zirconium oxide, yttrium stabilized zirconium oxide, titanium nitride, zirconium nitride, cubic boron nitride, aluminum nitride, titanium boride, zirconium boride, titanium carbide, tungsten carbide, vanadium carbide, boron carbide, zirconium carbide, niobium boride, carbide, silicon carbide, strontium titanate, tantalum carbide, cerium oxide, chromium boride, chromium oxide, beryllium oxide, scandium oxide, tungsten and tungsten alloys, magnesium oxide, mullite, diamond, cordierite, ferrite and garnet.
